(19) United States
(12) Patent Application Publication
(10) Pub. No.: US 2025/0140681 A1
(43) Pub. Date: May 1, 2025

(54) HIGH VOLTAGE CAPACITOR FORMED IN PCB FABRICATION

(71) Applicant: Allegro MicroSystems, LLC, Manchester, NH (US)

(72) Inventors: Felix Palumbo, Buenos Aires (AR); Thomas S. Chung, Merrimack, NH (US); Maxim Klebanov, Palm Coast, FL (US)

(73) Assignee: Allegro MicroSystems, LLC, Manchester, NH (US)

(21) Appl. No.: 18/499,345

(22) Filed: Nov. 1, 2023

(51) Int. Cl. H01L 23/522

(52) U.S. Cl. CPC H01L 23/5223; H10D 1/692; H01L 23/5226

(57) ABSTRACT

Example embodiments include methods and apparatus for a structure having a capacitor, where the structure includes a plurality of inter-metal dielectric (IMD) layers above a substrate, a plurality of metal layers between respective IMD layers. In embodiments, BEOL metal regions and interconnects form plates of the capacitor. In example embodiments, lateral capacitors can be formed away from the substrate.

### BACKGROUND

As is known in the art, capacitors have voltage ratings above which they may not perform properly or may fail. It is desirable in some applications to have capacitors with relatively high breakdown voltages formed as part of circuit board fabrication. However, fabrication technologies have certain limitations for forming capacitors having high breakdown voltages using conventional techniques.

### SUMMARY

Example embodiments of the disclosure provide methods and apparatus for a structure having a capacitor formed in metal layers and processing interconnects, such as BEOL interconnects, in circuit board fabrication. BEOL interconnect layers can form a capacitor with enhanced breakdown voltage and relatively low coupling capacitance. In embodiments, a BEOL capacitor has a cylindrical shape with concentric electrodes. In some embodiments, the BEOL capacitor is a lateral capacitor with plates spaced apart at a given distance above a substrate. With this arrangement, a uniform distribution of the electric fields is achieved so that the area required to isolate contacts in FEOL processing is reduced as compared with known configurations. In addition, for example, CMOS device processing allows integration in the same silicon as the high voltage capacitor with CMOS devices.

In one aspect, an assembly comprises: a substrate having a major surface; inter-metal dielectric (IMD) layers above the major surface of the substrate; metal layers between the respective IMD layers; a capacitor having first and second plates, wherein the first plate comprises a first metal region in a first one of the metal layers and at least one metal BEOL interconnect located in a first one of the IMD layers and connected to the first metal region.

An assembly can include one or more of the following features: the first and second plates are formed in the first one of the metal layers, the first and second plates form a cylindrical shape for the capacitor, the first plate is aligned with a center of the cylindrical shape, the first and second plates are located to maximize a distance to the substrate, an impedance of the capacitor is formed by the first metal region and the at least one metal BEOL interconnect, the first plate comprises a second metal region in a second one of the metal layers and at least one metal BEOL interconnect located in a second one of the IMD layers and connected to the second metal region, wherein the first and second metal regions and the BEOL interconnects in the first and second ones of the IMD layers are electrically connected, a shallow trench isolation layer on the substrate aligned with capacitor, the capacitor has a symmetrical shape, the first and second plates are located in different ones of the metal layers and are vertically aligned with respect to the major surface of the substrate, a conductive path from an uppermost surface of the assembly to the second plate through interconnects in the IMD layers and metal regions in the metal layers, the first plate is configured for high voltage and the second plate is configured for low voltage, the first and second plates are laterally separated by at least 10 μm, and/or the first and second plates are laterally separated by a distance equal to or greater than 100 μm.

In another aspect, a method to firm an assembly comprises: providing a substrate having a major surface; forming inter-metal dielectric (IMD) layers above the major surface of the substrate; forming metal layers between the respective IMD layers; forming a capacitor having first and second plates, wherein the first plate comprises a first metal region in a first one of the metal layers and at least one metal BEOL interconnect located in a first one of the IMD layers and connected to the first metal region.

A method can include one or more of the following features: the first and second plates are formed in the first one of the metal layers, the first and second plates form a cylindrical shape for the capacitor, the first plate is aligned with a center of the cylindrical shape, the first and second plates are located to maximize a distance to the substrate, an impedance of the capacitor is formed by the first metal region and the at least one metal BEOL interconnect, the first plate comprises a second metal region in a second one of the metal layers and at least one metal BEOL interconnect located in a second one of the IMD layers and connected to the second metal region, wherein the first and second metal regions and the BEOL interconnects in the first and second ones of the IMD layers are electrically connected, a shallow trench isolation layer on the substrate aligned with capacitor, the capacitor has a symmetrical shape, the first and second plates are located in different ones of the metal layers and are vertically aligned with respect to the major surface of the substrate, a conductive path from an uppermost surface of the assembly to the second plate through interconnects in the IMD layers and metal regions in the metal layers, the first plate is configured for high voltage and the second plate is configured for low voltage, the first and second plates are laterally separated by at least 10 μm, and/or the first and second plates are laterally separated by a distance equal to or greater than 100 μm.

### BRIEF DESCRIPTION OF THE DRAWINGS

The foregoing features of this disclosure, as well as the disclosure itself, may be more fully understood from the following description of the drawings in which:

FIG. 1A is a partial cross-sectional view and FIG. 1B is a top view of an example capacitor;

FIG. 2 is a partial cross-sectional view of another example capacitor;

FIG. 3 is a partial cross-sectional view of another example capacitor, which has plates vertically spaced from a substrate;

FIG. 4 is a schematic representation showing an example capacitor and example dimensions; and

FIG. 5 is a schematic representation of an example capacitor having an interdigitated comb configuration.

### DETAILED DESCRIPTION

Before describing example embodiments of the disclosure, some information is provided. Front-end-of-the-line (FEOL) processing refers to a first portion of IC fabrication in which devices, such as transistors, capacitors, resistors, diodes, and the like, are patterned. FEOL does not typically include the deposition of metal interconnect layers. FEOL can include shallow trench isolation (STI), gate, well, source, and drain formation

Back end of line (BEOL) refers to the part of the IC fabrication process in which individual devices, such as transistors, capacitors, diodes, resistors, etc., are connected to wiring on the wafer metallization layer. It is understood that after front end of the line (FEOL) processing, a wafer does not have wires so that transistors, and the like, are isolated. BEOL processing typically begins when the first layer of metal is deposited on the wafer. BEOL generally includes contacts, insulating layers, metal levels, and bonding sites for chip-to-package connections. Any practical number of layers can be added in BEOL processing. BEOL can include silicidation of source and drain regions and the polysilicon region, adding dielectric layers, adding metal layers, adding inter-metal dielectric (IMD) layers, forming vias between metal layers, and passivation.

As in well known in the art, and as used herein CMOS semiconductor processing is classified in two main parts: the front-end-of-line (FEOL) and the back-end-of-line (BEOL). The FEOL comprises the process steps that are related to the transistor itself, including the gate of the transistor. The BEOL process constructs metallic “interconnects” to allow transistors to communicate with each other.

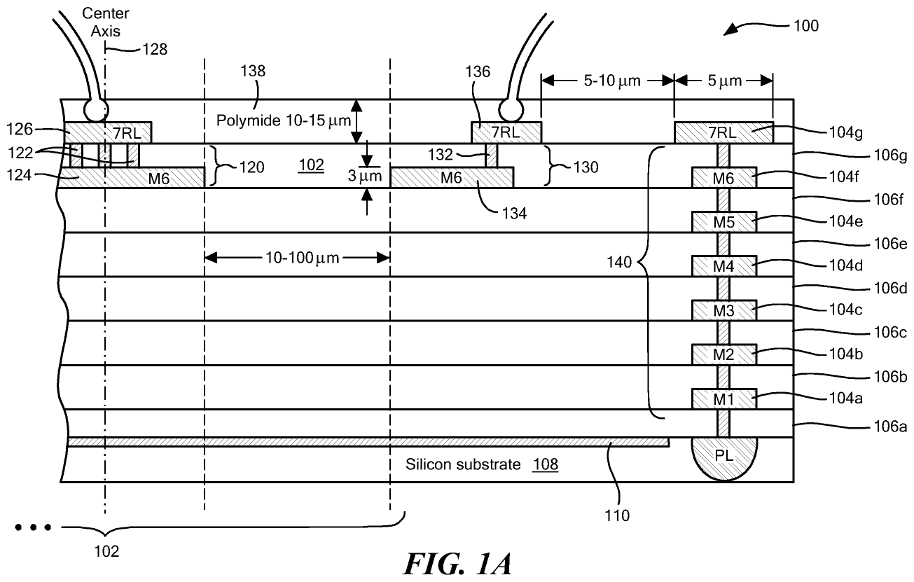

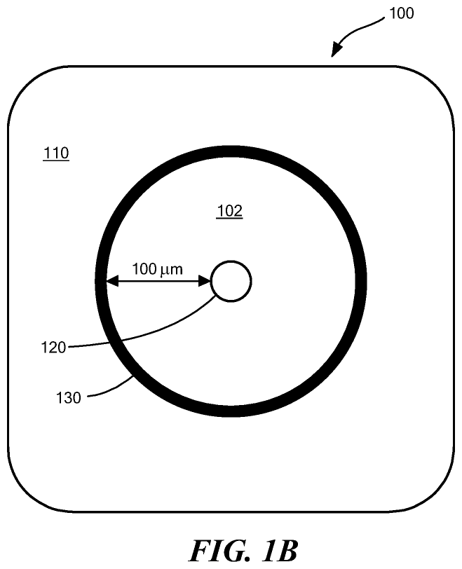

FIG. 1A is a partial cross-section and FIG. 1B is a top view of a structure 100 having a capacitor 102 formed by metal regions and interconnects between metal layers, such as BEOL interconnects. It is understood that FIG. 1A shows about half of a cylindrical capacitor 102 and FIG. 1B shows a top view of the entire capacitor 102. The structure 100 includes a series of metal layers 104a-g and inter metal dielectric (IMD) layers 106a-g between metal layers. The metal layers 104 and IMD layers 106 are formed on a substrate 108, such as a silicon substrate. A shallow trench isolation (STI) layer 110 can be formed on the substrate 108. An STI layer 110 prevents current leakage between adjacent device components. The STI layer 110 is formed prior to transistor formation.

In the illustrated embodiment, a first plate 120 of the capacitor 102 is formed in the center of the capacitor. The first plate 120 comprises at least one first metal interconnect 122 that connects a first metal portion 124 in the sixth metal layer 104f and a first metal contact 126 that may form a first terminal of the capacitor, which may be a high voltage contact for the capacitor. In embodiments, the metal interconnects 122, the first metal portion 124, and the first metal contact 126 combine to form the first plate 120 of the capacitor. In the illustrated embodiment, the first plate 120 extends vertically, i.e., is perpendicular to the major surface of the substrate 108, along an axis of symmetry 128 of the cylindrical capacitor.

A second plate 130 of the capacitor 102 is formed by at least one second metal interconnect 132 connecting a second metal portion 134 in the sixth metal layer 104f and a second metal contact 136 that may form a second terminal of the capacitor. In the illustrated embodiment, the first plate 120 of the capacitor is located in the center of capacitor. In embodiments, the first plate 120 is the higher voltage contact and the second plate 130 is the lower voltage contact. In embodiments, a layer of material 138, such as polymide, can be formed over the top-most IMD layer. To prevent top side voltage breakdown, a thick passivation layer can be added. In addition, a polyamide layer of 10 um-15 um should be included over the entire device. In embodiments, the capacitor 102 is formed in layers that are furthest from the substrate 108, as described more fully below.

In some embodiments, a conductive path 140 can be formed from the topmost metal layer 104g to the substrate 108 using metal interconnects in each IMD layer 106 and metal portions in each metal layer 104.

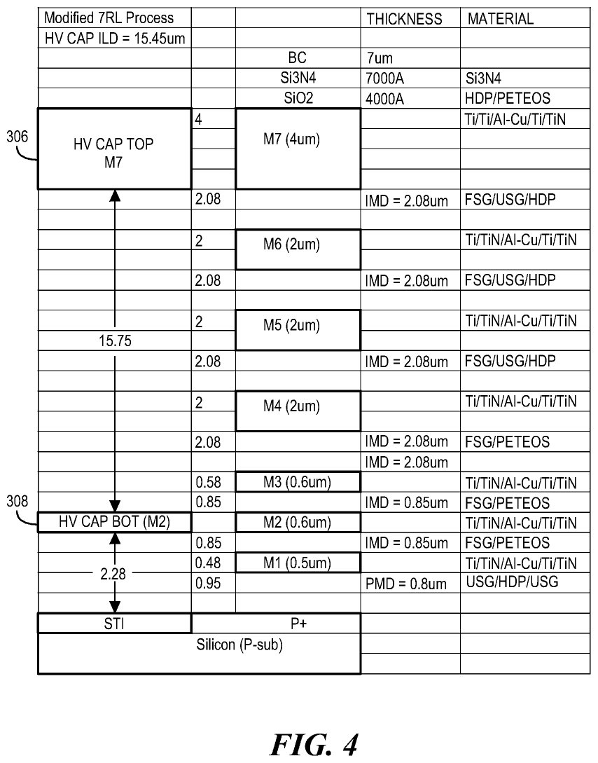

In example embodiments, a lateral distance from edges of the first and second plates 102, 104 can vary from about 10 μm to about 100 μm. Example distances are included to facilitate an understanding of illustrative embodiments of the disclosure and are not intended to limit the scope of the invention as claimed in any way. It is noted that typical widths for the metal layers in BEOL are included in FIG. 4. It is understood that widths can be selected to meet the needs of a particular application in an example range of 0.2 um-0.8 um to about 2 um-4 um.

It is understood that a wide range of lateral and vertical distances between components of the structure can vary to meet the needs of a particular application. It is further understood that any practical number of layers can be used in the structure and that one or more capacitors can be formed in any practical number of layers.

As used herein a lateral capacitor refers to a capacitor having plates that extend perpendicularly to a major surface of the substrate. A major surface of the substrate refers to a surface having greater surface area than side surfaces of the substrate. A major surface is understood to be a top or bottom surface of the substrate. In the example embodiment of FIGS. 1A and 1B, the capacitor 102 is a lateral capacitor with first and second plates 120, 130 spaced apart by a given width, e.g., 10 μm to about 100 μm, across the substrate 108.

In embodiments, a capacitor, such as capacitor 102 in FIGS. 1A and 1B, comprises a metal-insulator-Metal (MIM) capacitor with an operating range in the order of 10 kV. In example embodiments, a device is configured to have an operating voltage in the range of 10 kV. It is understood that the operating level depends on the thickness of the capacitor. In example capacitor embodiments having horizontal plates it is possible to increase the distance to reach desired values.

Using BEOL interconnect metals in example embodiments of the disclosure enables a capacitive structure with a high breakdown voltage and low coupling capacitance to FEOL devices. With this arrangement, in contrast to conventional structures, example embodiments provide a separation gap between contacts that can reach hundreds of microns (100 um) to enable capacitances in the order of 1e-18F.

In addition, symmetrical capacitor shapes, such as cylindrical, allow a uniform distribution of the electric fields so as to reduce the area needed to isolate the capacitor contacts to FEOL. The thickness of the isolation layers to FEOL is in the order of 6 um-8 um. In embodiments, CMOS processing allows integration in the same silicon of a high voltage capacitor and CMOS devices.

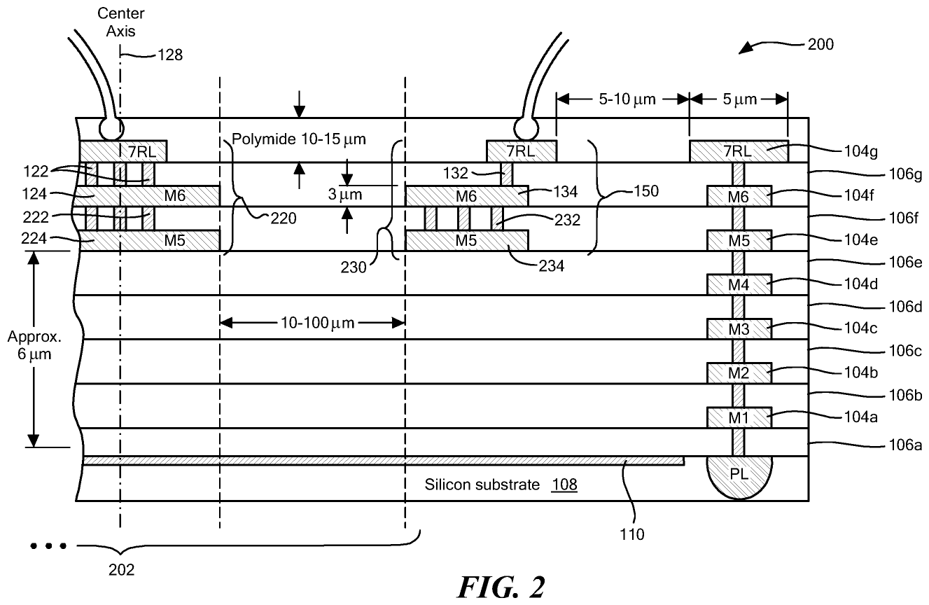

FIG. 2 shows an example structure 200 having a layer of metal interconnects added to the structure 100 of FIGS. 1A and 1B, where like reference numbers indicate like elements. In the illustrated embodiment, a first plate 220 of the capacitor 202 includes interconnects 222 in IMD layer 106f and metal portion 224 in metal layer 104e in addition to interconnects 122 and metal portion 124 of FIG. 1. The second plate 230 includes interconnects 232 in IMD layer 106f and metal portion 234 in metal layer 104e in addition to interconnects 132 and metal portion 134. With this arrangement, the parasitic capacitance of capacitor 202 is extended vertically. With this extension, the capacitor 202 is closer to the major surface of the substrate 108.

It will be appreciated that cylindrical capacitor shapes reduce the isolation gap between different sections of the integrated circuit. The substrate 108 parasitic capacitance is removed/controlled by the thickness of the IMD isolation layers 106 to the FEOL. In embodiments, the IMD layers 106 are in the order of 6 um-8 um. In embodiments, the STI layer 110 extends over the entire region of the capacitor 202.

In embodiments having both capacitor plates on same metal level, the lateral BV (Breakdown Voltage) strength will be reduced as the BV may develop along oxide/oxide interfaces where metal was etched off. Plate distance can be added to compensate this effect.

It will be appreciated that the larger the distance between plates, the smaller the capacitance of the capacitor formed by the plates. In embodiments, to reduce this intrinsic effect, a periphery of the capacitor plate can be formed using thicker metal, and/or more than one metal layer in parallel (e.g., M6 and M5). In some embodiments, circular symmetry can be modified to have parallel runs. In some embodiments, lateral trenches are formed to provide additional isolation for the bottom plate of the capacitor.

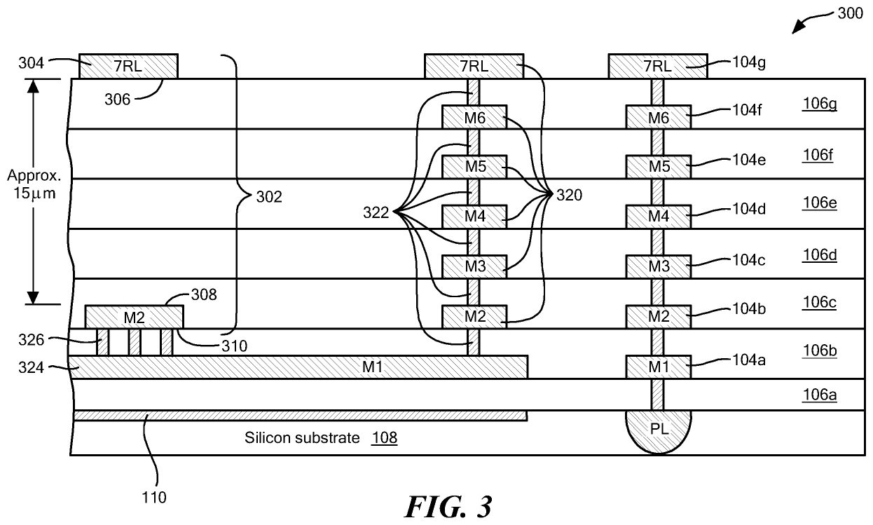

FIG. 3 shows an example structure 300 in partial cross-section having a capacitor 302 with a vertical orientation formed using BEOL metal layers and interconnects. In the illustrated embodiment, a first plate 304 is formed by a first metal region 306 in metal layer 104g and a second plate 308 is formed by a second metal region 310 in metal layer 104b. In the illustrated embodiment, the first and second plates 304, 308 are spaced apart by about 15 μm. The first plate 304 may be coupled to a high voltage terminal and the second plate 308 may be coupled to a low voltage terminal. In the illustrated embodiment, a series of metal regions 320 in metal layers 104a-g and interconnects 322 in IMD layers 106b-g form an electrical connection from the top surface of the structure 300 to an elongate metal region 324 in metal layer 104a extending laterally above the substrate 108 to be underneath at least a portion of the second plate 308. This enables a low voltage connection to the second plate 308 from the top of the structure 300. At least one interconnect 326 can connect the second plate 308 to metal region 324. It is understood that metal region 324, interconnects 326, and second plate 308 contribute to the structure and impedance characteristics of the capacitor 302.

FIG. 4 shows example BEOL materials and distances for the example vertical capacitor 302 with first and second plates 306, 308 of FIG. 3 in accordance with illustrative embodiments of the disclosure. The illustrated embodiment, includes metal layers M1-M7 and IMD layers and a doped P+ region to enhance isolation. In embodiments, the example dimensions and materials are applicable to the lateral capacitor embodiments of FIGS. 1A and 2.

It is understood that example capacitor embodiments are applicable to a wide range of circuits and applications, such as isolated gate drivers, motor drivers, and power circuits in general in which space and cost and capacitor operating voltage are considerations.

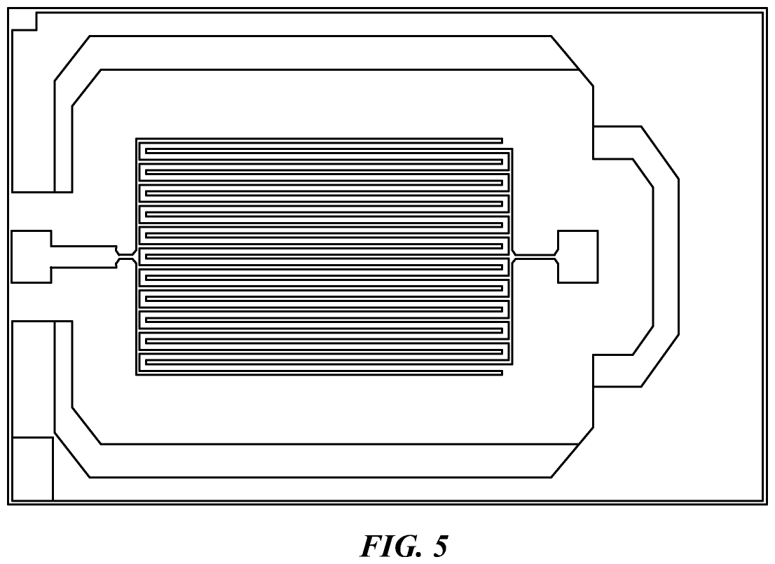

It is further understood that while example capacitor embodiments are shown and described in cylindrical shapes, it is understood that any suitable geometry, such as ovular, elliptical, etc., can be used to meet the needs of a particular application. For example, FIG. 5 shows a capacitor having an interdigitated comb configuration.

In addition, it is understood that any suitable dielectric materials can be used to form example capacitor configuration. In some embodiments, dielectric materials, such as boron carbides (BCH) and boron nitrides (BNH) can be used. It is understood that any useful BEOL dielectric and metal can be used to meet the needs of a particular application.

It is noted that various connections and positional relationships (e.g., over, below, adjacent, etc.) may be used to describe elements and components in the description and drawings. It is understood that relative terms are intended to facilitate an understanding of example embodiments of the disclosure and are not intended to limit the scope of the invention as claimed to the relative positions. These connections and/or positional relationships, unless specified otherwise, can be direct or indirect, and the described concepts, systems, devices, structures, and techniques are not intended to be limiting in this respect. Accordingly, a coupling of elements can refer to either a direct or an indirect coupling, and a positional relationship between elements can be a direct or indirect positional relationship.

The following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

The terms “one or more” and “at least one” indicate any integer number greater than or equal to one, i.e., one, two, three, four, etc.; though, where context admits, those terms may indicate fractional values. The term “plurality” indicates any integer number greater than one. The term “connection” can include an indirect “connection” and a direct “connection.”

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not. Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements. Use of ordinal terms such as “first,” “second,” “third,” etc., in the claims to modify a claim clement does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements. The terms “substantially” and “about” refer to values that are within ±10% of a comparative measure unless explicitly defined in a different way.

Having described preferred embodiments, it will now become apparent to one of ordinary skill in the art that other embodiments incorporating their concepts may be used. Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims. All publications and references cited in this patent are expressly incorporated by reference in their entirety. It is understood that these embodiments should not be limited to disclosed embodiments, but rather should be limited only by the spirit and scope of the appended claims.

What is claimed is:

1. An assembly, comprising:
a substrate having a major surface;
inter-metal dielectric (IMD) layers above the major surface of the substrate;
metal layers between the respective IMD layers;
a capacitor having first and second plates, wherein the first plate comprises a first metal region in a first one of the metal layers and at least one metal BEOL interconnect located in a first one of the IMD layers and connected to the first metal region.

2. The assembly according to claim 1, wherein the first and second plates are formed in the first one of the metal layers.

3. The assembly according to claim 2, wherein the first and second plates form a cylindrical shape for the capacitor.

4. The assembly according to claim 3, wherein the first plate is aligned with a center of the cylindrical shape.

5. The assembly according to claim 1, wherein the first and second plates are located to maximize a distance to the substrate.

6. The assembly according to claim 1, wherein an impedance of the capacitor is formed by the first metal region and the at least one metal BEOL interconnect.

7. The assembly according to claim 1, wherein the first plate comprises a second metal region in a second one of the metal layers and at least one metal BEOL interconnect located in a second one of the IMD layers and connected to the second metal region, wherein the first and second metal regions and the BEOL interconnects in the first and second ones of the IMD layers are electrically connected.

8. The assembly according to claim 1, further including a shallow trench isolation layer on the substrate aligned with capacitor.

9. The assembly according to claim 1, wherein the capacitor has a symmetrical shape.

10. The assembly according to claim 1, wherein the first and second plates are located in different ones of the metal layers and are vertically aligned with respect to the major surface of the substrate.

11. The assembly according to claim 10, further including a conductive path from an uppermost surface of the assembly to the second plate through interconnects in the IMD layers and metal regions in the metal layers.

12. The assembly according to claim 1, wherein the first plate is configured for high voltage and the second plate is configured for low voltage.

13. The assembly according to claim 1, wherein the first and second plates are laterally separated by at least 10 μm.

14. The assembly according to claim 1, wherein the first and second plates are laterally separated by a distance equal to or greater than 100 μm.

15. A method to firm an assembly, comprising:
providing a substrate having a major surface;
forming inter-metal dielectric (IMD) layers above the major surface of the substrate;
forming metal layers between the respective IMD layers;
forming a capacitor having first and second plates, wherein the first plate comprises a first metal region in a first one of the metal layers and at least one metal BEOL interconnect located in a first one of the IMD layers and connected to the first metal region.

16. The method according to claim 15, wherein the first and second plates are formed in the first one of the metal layers.

17. The method according to claim 16, wherein the first and second plates form a cylindrical shape for the capacitor.

18. The method according to claim 17, wherein the first plate is aligned with a center of the cylindrical shape.

19. The method according to claim 15, wherein the first and second plates are located to maximize a distance to the substrate.

20. The method according to claim 15, wherein an impedance of the capacitor is formed by the first metal region and the at least one metal BEOL interconnect.

21. The method according to claim 15, wherein the first plate comprises a second metal region in a second one of the metal layers and at least one metal BEOL interconnect located in a second one of the IMD layers and connected to the second metal region, wherein the first and second metal regions and the BEOL interconnects in the first and second ones of the IMD layers are electrically connected.

22. The method according to claim 15, further including forming a shallow trench isolation layer on the substrate aligned with capacitor.

23. The method according to claim 15, wherein the capacitor has a symmetrical shape.

24. The method according to claim 15, wherein the first and second plates are located in different ones of the metal layers and are vertically aligned with respect to the major surface of the substrate.

25. The method according to claim 24, further including a conductive path from an uppermost surface of the assembly to the second plate through interconnects in the IMD layers and metal regions in the metal layers.

26. The method according to claim 15, wherein the first plate is configured for high voltage and the second plate is configured for low voltage.

27. The method according to claim 15, wherein the first and second plates are laterally separated by at least 10 μm.

28. The method according to claim 15, wherein the first and second plates are laterally separated by a distance equal to or greater than 100 μm.
